(19) United States
(12) Patent Application Publication
(10) Pub. No.: US 2019/0207115 A1
(43) Pub. Date: Jul. 4, 2019

(54) PROCESS FOR MAKING AN ORGANIC CHARGE TRANSPORTING FILM

(71) Applicant: Dow Global Technologies LLC, Milland, MI (US)

(72) Inventors: Robert David GRIGG, Midland, MI (US); Liam P. Spencer, Freeport, TX (US); John W. Kramer, Midland, MI (US); Chun Liu, Midland, MI (US); David D. Devore, Midland, MI (US); Shaoguang Feng, Shanghai (CN); Jichang Feng, Shanghai (CN); Minrong Zhu, Shanghai (CN); Yang Li, Shanghai (CN); Sukrit Mukhopadhyay, Midland, MI (US); Anatoliy N. Sokolov, Midland, MI (US); Matthew S. Remy, Midland, MI (US); Peter Trefonas, Medway, MA (US); Bethany Neilson, Freeport, TX (US)

(21) Appl. No.: 16/311,874

(22) PCT Filed: Jun. 28, 2016
(86) PCT No.: PCT/CN2016/087408

§ 371 Date: Dec. 20, 2018

(51) Int. Cl. H01L 51/00; C08F 112/14; C08F 112/32; C09D 125/18; C09D 5/24

(52) U.S. Cl. CPC H01L 51/0039; C08F 112/14; C08F 112/32; H01L 51/5056; C09D 5/24; H01L 2251/556; C09D 125/18

(57) ABSTRACT

A polymer which has Mₙ at least 4,000 and comprises polymerized units of a compound of formula NAr¹A²A³, wherein Ar¹, Ar² and Ar³ independently are C₆-C₄₀ aromatic substituents; Ar¹, Ar² and Ar³ collectively contain no more than one nitrogen atom and at least one of Ar¹, Ar² and Ar³ contains a vinyl group attached to an aromatic ring.

### FIELD OF THE INVENTION

The present invention relates to a process for preparing an organic charge transporting film.

### BACKGROUND OF THE INVENTION

There is a need for an efficient process for manufacturing an organic charge transporting film for use in a flat panel organic light emitting diode (OLED) display. Solution processing is one of the leading technologies for fabricating large flat panel OLED displays by deposition of OLED solution onto a substrate to form a thin film followed by cross-linking and polymerization. Currently, solution processable polymeric materials are cross-linkable organic charge transporting compounds. For example, U.S. Pat. No. 7,037,994 discloses an antireflection film-forming formulation comprising at least one polymer containing an acetoxymethylacenapthylene or hydroxyl methyl acenaphthylene repeating unit and a thermal or photo acid generator (TAG, PAG) in a solvent. However, this reference does not disclose the formulation described herein.

### SUMMARY OF THE INVENTION

The present invention provides a polymer having Mₙ at least 4,000 and comprising polymerized units of a compound of formula NAr¹Ar²Ar³, wherein Ar^{t}, Ar² and Ar³ independently are C₆-C₄₅ aromatic substituents; Ar¹, Ar² and Ar³ collectively contain no more than one nitrogen atom and at least one of Ar¹, Ar² and Ar³ contains a vinyl group attached to an aromatic ring.

### DETAILED DESCRIPTION OF THE INVENTION

Percentages are weight percentages (wt %) and temperatures are in ° C., unless specified otherwise. Operations were performed at room temperature (20-25° C.), unless specified otherwise. Boiling points are measured at atmospheric pressure (ca. 101 kPa). Molecular weights are in Daltons and molecular weights of polymers are determined by Size Exclusion Chromatography using polystyrene standards.

As used herein, the term “aromatic substituent” refers to a substituent having at least one aromatic ring, preferably at least two. A cyclic moiety which contains two or more fused rings is considered to be a single aromatic ring, provided that all ring atoms in the cyclic moiety are part of the aromatic system. For example, naphthyl, carbazolyl and indolyl are considered to be single aromatic rings, but fluorenyl is considered to contain two aromatic rings because the carbon atom at the exposition of fluorene is not part of the aromatic system.

Preferably, compound of formula NAr¹Ar²Ar³ contains no arylmethoxy linkages. An arylmethoxy linkage is an ether linkage having two benzylic carbon atoms attached to an oxygen atom. A benzylic carbon atom is a carbon atom which is not part of an aromatic ring and which is attached to a ring carbon of an aromatic ring having from 5 to 30 carbon atoms (preferably 5 to 20), preferably a benzene ring. Preferably, the compound contains no linkages having only one benzylic carbon atom attached to an oxygen atom. Preferably, an arylmethoxy linkage is an ether, ester or alcohol. Preferably, the compound of formula NAr¹Ar²Ar³ has no ether linkages where either carbon is a benzylic carbon, preferably no ether linkages at all.

Preferably, the compound of formula NAr¹Ar²Ar³ contains a total of 4 to 12 aromatic rings; preferably at least 5 preferably at least 6; preferably no more than 10, preferably no more than 9, preferably no more than 8. Preferably, each of Ar¹, Ar² and Ar³ independently contains at least 10 carbon atoms, preferably at least 12; preferably no more than 42, preferably no more than 40, preferably no more than 35, preferably no more than 30, preferably no more than 25, preferably no more than 20. Aliphatic carbon atoms, e.g., C₁-C₆ hydrocarbyl substituents or non-aromatic ring carbon atoms (e.g., the 9-carbon of fluorene), are included in the total number of carbon atoms in an Ar substituent. Ar groups may contain heteroatoms, preferably N, O or S; preferably Ar groups contain no heteroatoms other than nitrogen. Preferably, only one vinyl group is present in the compound of formula NAr¹Ar²Ar³. Preferably, the compound does not have a vinyl group on a fused ring system, e.g., fluorenyl, carbazolyl or indolyl. Preferably, Ar groups consist of one or more of biphenylyl, fluorenyl, phenylenyl, carbazolyl and indolyl. In a preferred embodiment of the invention, two of Ar¹, Ar² and Ar³ are connected by at least one covalent bond. An example of this is the structure shown below

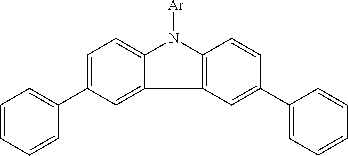

When a nitrogen atom in one of the aryl substituents is a triarylamine nitrogen atom, the Ar¹, Ar² and Ar³ groups can be defined in different ways depending on which nitrogen atom is considered to be the nitrogen atom in the formula NAr¹Ar²Ar³. In this case, the nitrogen atom and Ar groups are to be construed so as to satisfy the claim limitations.

An “organic charge transporting compound” is a material which is capable of accepting an electrical charge and transporting it through the charge transport layer. Examples of charge transporting compounds include “electron transporting compounds” which are charge transporting compounds capable of accepting an electron and transporting it through the charge transport layer, and “hole transporting compounds” which are charge transporting compounds capable of transporting a positive charge through the charge transport layer. Preferably, organic charge transporting compounds. Preferably, organic charge transporting compounds have at least 50 wt % aromatic rings (measured as the molecular weight of all aromatic rings divided by total molecular weight; non-aromatic rings fused to aromatic rings are included in the molecular weight of aromatic rings), preferably at least 60%, preferably at least 70%, preferably at least 80%, preferably at least 90%. Preferably the polymer comprises organic charge transporting compounds.

In a preferred embodiment of the invention, some or all materials used, including solvents and polymers, are enriched in deuterium beyond its natural isotopic abundance. All compound names and structures which appear herein are intended to include all partially or completely deuterated analogs.

Preferably, the polymer has Mₙ at least 6,000, preferably at least 8,000, preferably at least 10,000, preferably at least 20,000; preferably no greater than 10,000,000, preferably no greater than 1,000,000, preferably no greater than 500,000, preferably no greater than 300,000, preferably no greater than 200,000. Preferably, the polymer comprises at least 60% (preferably at least 80%, preferably at least 95%) polymerized monomers which contain at least five aromatic rings, preferably at least six; other monomers not having this characteristic may also be present.

Preferably, the polymers are at least 99% pure, as measured by liquid chromatography/mass spectrometry (LC/MS) on a solids basis, preferably at least 99.5%, preferably at least 99.7%. Preferably, the formulation of this invention contains no more than 10 ppm of metals, preferably no more than 5 ppm.

Preferred polymers useful in the present invention include, e.g., the following structures.

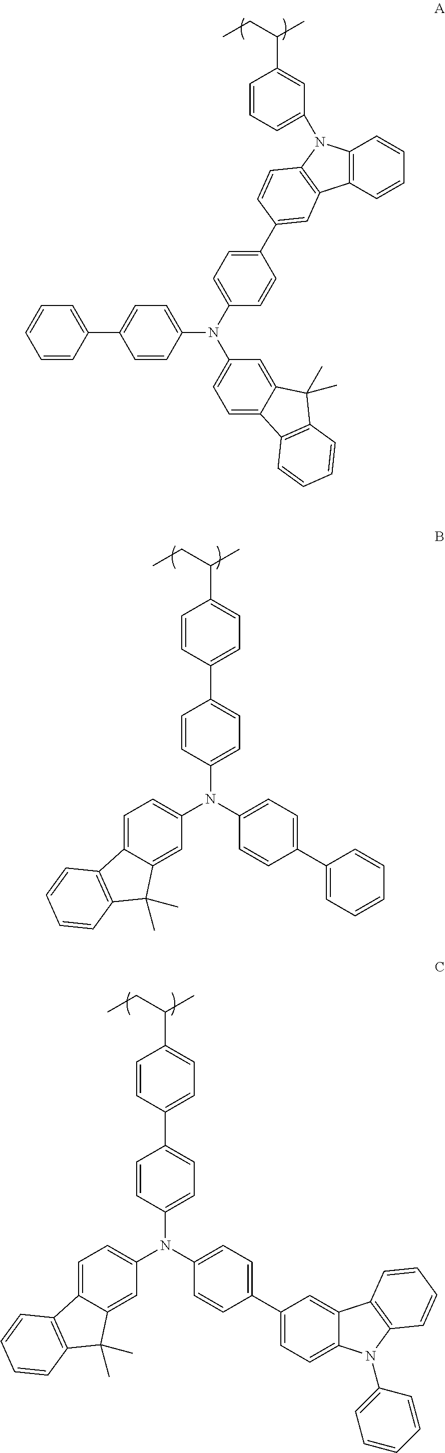

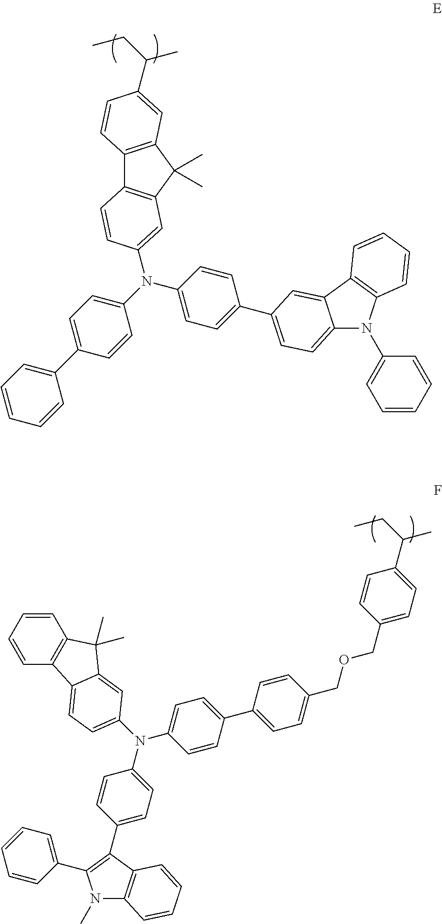

Crosslinking agents which are not necessarily charge transporting compounds may be included in the formulation as well. Preferably, these crosslinking agents have at least 60 wt % aromatic rings (as defined previously), preferably at least 70%, preferably at least 75 wt %. Preferably, the crosslinking agents have from three to five polymerizable groups, preferably three or four. Preferably, the polymerizable groups are ethenyl groups attached to aromatic rings. Preferred crosslinking agents are shown below

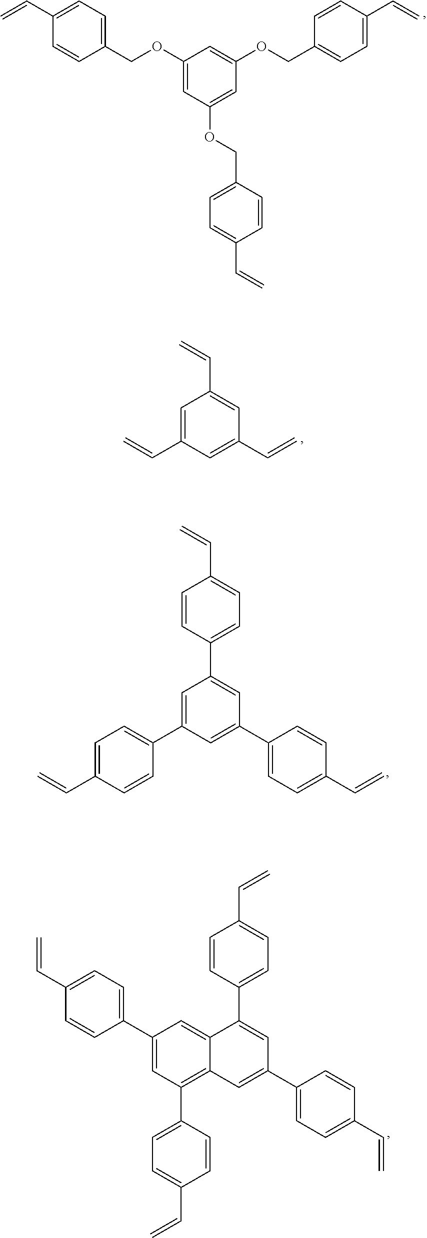

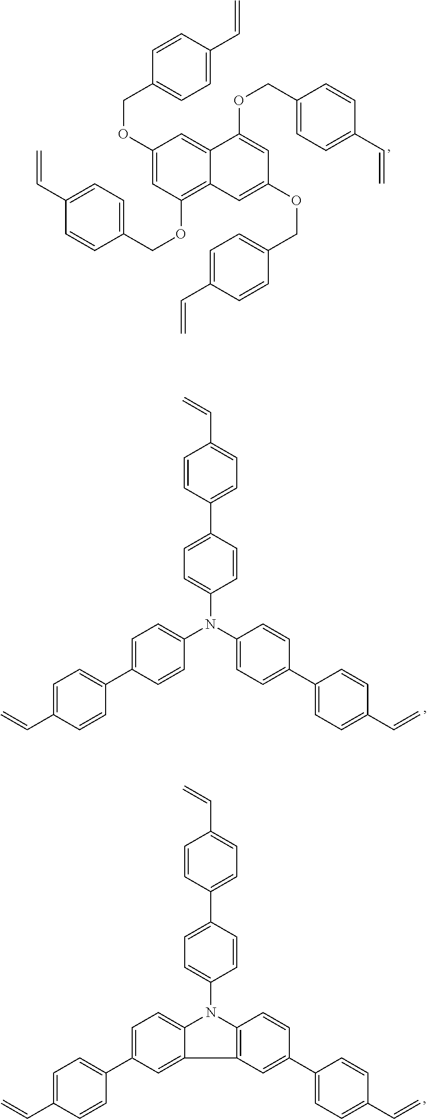

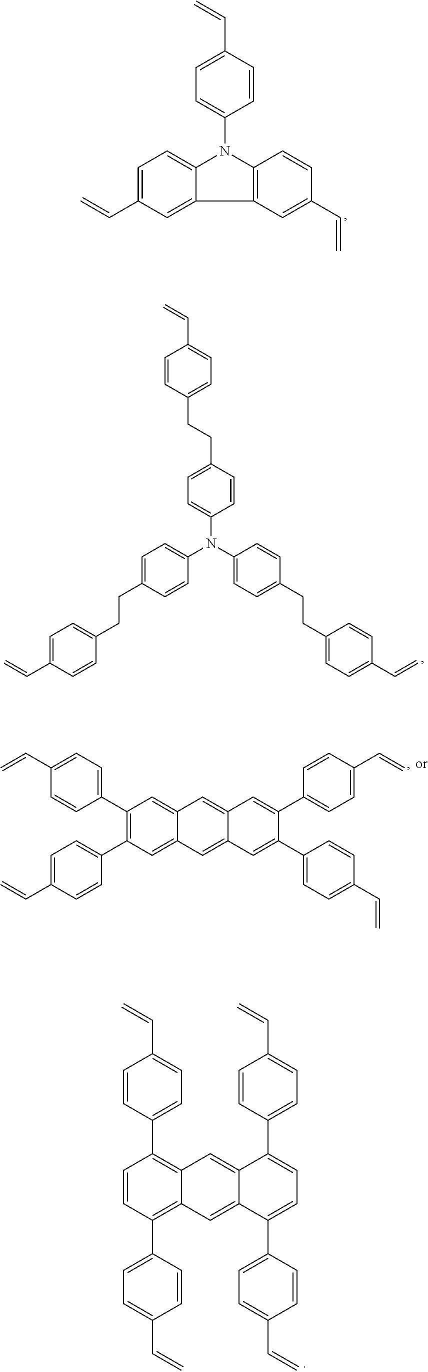

Preferably, solvents used in the formulation have a purity of at least 99.8%, as measured by gas chromatography-mass spectrometry (GC/MS), preferably at least 99.9%. Preferably, solvents have an RED value (relative energy difference as calculated from Hansen solubility parameter) less than 1.2, preferably less than 1.0, relative to the polymer, calculated using CHEMCOMP v2.8.50223.1 Preferred solvents include aromatic hydrocarbons and aromatic-aliphatic ethers, preferably those having from six to twenty carbon atoms. Anisole, xylene and toluene are especially preferred solvents.

Preferably, the percent solids of a formulation used to prepare the film, i.e., the percentage of polymers relative to the total weight of the formulation, is from 0.5 to 20 wt %; preferably at least 0.8 wt %, preferably at least 1 wt %, preferably at least 1.5 wt %; preferably no more than 15 wt %, preferably no more than 10 wt %, preferably no more than 7 wt %, preferably no more than 4 wt %. Preferably, the amount of solvents) is from 80 to 99.5 wt %; preferably at least 85 wt %, preferably at least 90 wt %, preferably at least 93 wt %, preferably at least 94 wt %; preferably no more than 99.2 wt %, preferably no more than 99 wt %, preferably no more than 98.5 wt %.

Preferably, the compound of formula NAr¹Ar²Ar³ is polymerized by known methods using a free-radical initiator, e.g., an azo compound, a peroxide or a hydrocarbyl initiator having structure R¹R²R³C—CR⁴R⁵R⁶, wherein R¹ to R⁶ are independently hydrogen or a C₁-C₂₀ hydrocarbyl group (preferably C₁-C₁₂), wherein different R groups may join together to form a ring structure, provided that at least one of R¹, R² and R³ is an aryl group and at least one of R⁴, R⁵ and R⁶ is an aryl group. When hydrocarbyl initiators are used, preferably the polymerization temperature is from 20-100° C.

The present invention is further directed to an organic charge transporting film comprising the polymer of the present invention and a process for producing it by coating the formulation on a surface, preferably another organic charge transporting film, and Indium-Tin-Oxide (TTO) glass or a silicon wafer. The film is formed by coating the formulation on a surface, prebaking at a temperature from 50 to 150° C. (preferably 80 to 120° C.), preferably for less than five minutes, followed by thermal annealing at a temperature from 120 to 280° C.; preferably at least 140° C., preferably at least 160° C., preferably at least 170° C.; preferably no greater than 230° C., preferably no greater than 215° C.

Preferably, the thickness of the polymer films produced according to this invention is from 1 nm to 100 microns, preferably at least 10 nm, preferably at least 30 nm, preferably no greater than 10 microns, preferably no greater than 1 micron, preferably no greater than 300 nm. The spin-coated film thickness is determined mainly by the solid contents in solution and the spin rate. For example, at a 2000 rpm spin rate, 2, 5, 8 and 10 wt % polymer formulated solutions result in the film thickness of 30, 90, 160 and 220 nm, respectively. The wet film shrinks by 5% or less after baking and annealing.

### EXAMPLES

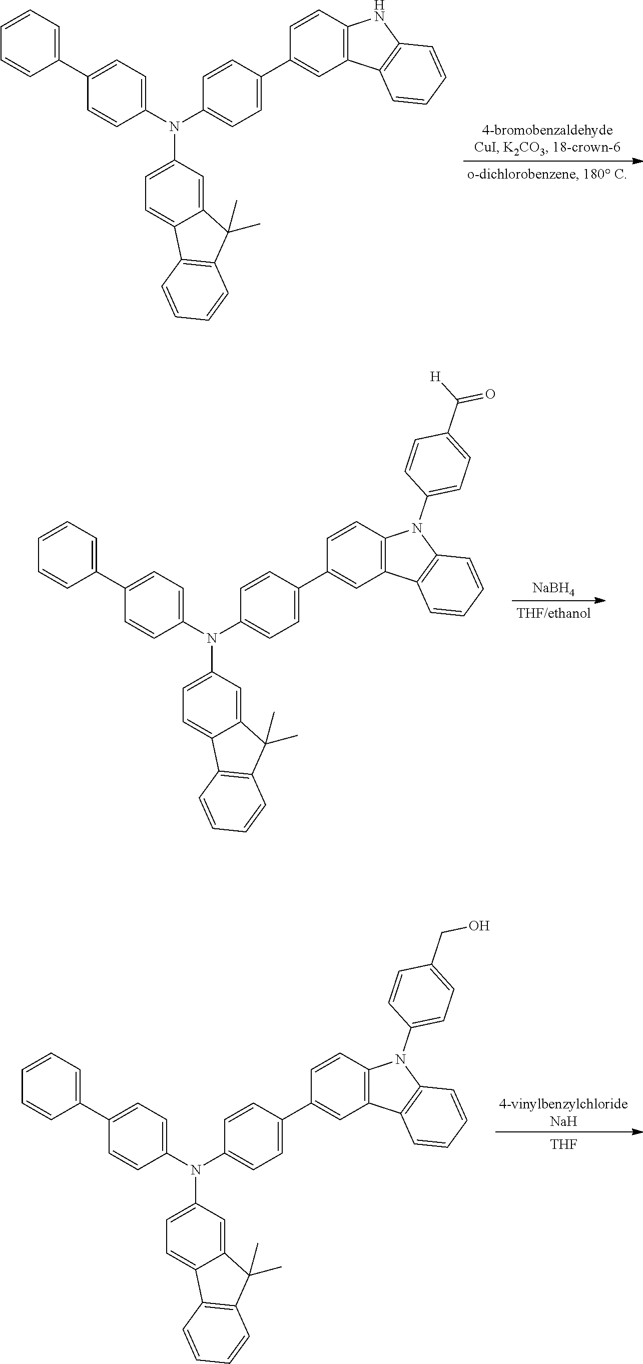 [SMILES: CC1(C)c2ccccc2-c2ccc(N(c3ccc(-c4ccccc4)cc3)c3ccc(-c4ccc5[nH]c6ccccc6c5c4)cc3)cc21 ; CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21 ; "NaBH4" ; "THF" ; CC1(C)c2ccccc2-c2ccc(N(c3ccc(-c4ccccc4)cc3)c3ccc(-c4ccc5c(c4)c4ccccc4n5-c4ccc(CO)cc4)cc3)cc21 ; "4-vinylbenzylchlorideNaH"]

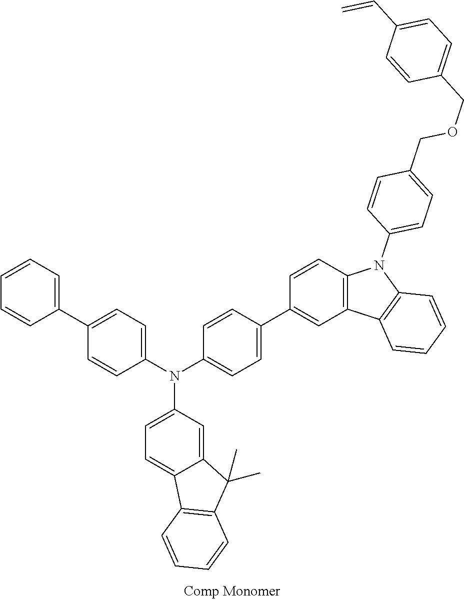 [SMILES: C=Cc1ccc(COCc2ccc(-n3c4ccccc4c4cc(-c5ccc(N(c6ccc(-c7ccccc7)cc6)c6ccc7c(c6)C(C)(C)c6ccccc6-7)cc5)ccc43)cc2)cc1]

### Synthesis of 4-(3-(4-([1,1′-biphenyl]-4-yl(9,9-dimethyl-9H-fluoren-2-yl)amino)phenyl)-9H-carbazol-9-yl)benzaldehyde

A round bottom flask was charged with N-(4-(9H-carbazol-3-yl)phenyl)-N-([1,1′-biphenyl]-4-yl)-9,9-dimethyl-9H-fluoren-2-amine (2.00 g, 3.32 mmol, 1.0 equiv), 4-bromobenzaldehyde (0.737 g, 3.98 mmol, 1.2 equiv), CuI (0.126 g, 0.664 mmol, 0.2 equiv), potassium carbonate (1.376 g, 9.954 mmol, 3.0 equiv), and 18-crown-6 (86 mg, 10 mol %). The flask was flushed with nitrogen and connected to a reflux condenser. 10.0 mL dry, degassed, 1,2-dichlorobenzene was added, and the mixture was refluxed for 48 hours. The cooled solution was quenched with sat. aq. NH₄Cl, and extracted with dichloromethane. Combined organic fractions were dried, and solvent removed by distillation. The crude residue was purified by chromatography on silica gel (hexane/chloroform gradient), which gave product as a bright yellow solid (2.04 g, 87%). ¹H NMR (500 MHz, CDCl₃) δ 10.13 (S, 1H), 8.37 (d, J=2.0 HZ, 1H), 8.20 (dd, J==7.7, 1.0 Hz, 1H), 8.16 (d, J=8.2 Hz, 2H), 7.83 (d, J=8.1 Hz, 2H), 7.73-7.59 (m, 7H), 7.59-7.50 (m, 4H), 7.50-7.39 (m, 4H), 7.39-7.24 (m, 10H), 7.19-7.12 (m, 1H), 1.47 (s, 6H). ¹³C NMR (126 MHz, CDCl₃) δ 190.95, 155.17, 153.57, 147.21, 146.98, 146.69, 143.38, 140.60, 140.48, 139.28, 138.93, 135.90, 135.18, 134.64, 134.46, 133.88, 131.43, 128.76, 127.97, 127.81, 126.99, 126.84, 126.73, 126.65, 126.54, 126.47, 125.44, 124.56, 124.44, 124.12, 123.98, 123.63, 122.49, 120.96, 120.70, 120.57, 119.47, 118.92, 118.48, 110.05, 109.92, 46.90, 27.13.

### Synthesis of (4-(3-(4-([1,1′-biphenyl]-4-yl(9,9-dimethyl-9H-fluoren-2-yl)amino)phenyl)-9H-carbazol-9-yl)phenyl)methanol

Around bottom flask was charged with 4-(3-(4-([1,1′-biphenyl]-4-yl(9,9-dimethyl-9H-fluoren-2-yl)amino)phenyl)-9H-carbazol-9-yl)benzaldehyde (4.36 g, 6.17 mmol, 1.00 equiv) under a blanket of nitrogen. The material was dissolved in 40 mL 1:1 THF/EtOH. Sodium borohydride (0.280 g, 7.41 mmol, 1.20 equiv) was added in portions and the material stirred for 3 hours (consumption of starting material indicated by TLC). The reaction mixture was cautiously quenched with 1M HCl, and the product was extracted with portions of dichloromethane. Combined organic fractions were washed with sat. aq. Sodium bicarbonate, dried with MgSO₄ and concentrated to a crude residue. The material was purified by chromatography (hexane/dichloromethane gradient), which gave the product was a white solid (3.79 g, 85%). ¹H NMR (500 MHz, CDCl₃) δ 8.35 (s, 1H), 8.19 (dt, J=7.8, 1.1 Hz, 1H), 7.73-7.56 (m, 11H), 7.57-7.48 (m, 2H), 7.48-7.37 (m, 6H), 7.36-7.23 (m, 9H), 7.14 (s, 1H), 4.84 (s, 2H), 1.45 (s, 6H). ¹³C NMR (126 MHz, CDCl₃) δ 155.13, 153.56, 147.24, 147.02, 146.44, 141.27, 140.60, 140.11, 140.07, 138.94, 136.99, 136.33, 135.06, 134.35, 132.96, 128.73, 128.44, 127.96, 127.76, 127.09, 126.96, 126.79, 126.62, 126.48, 126.10, 125.15, 124.52, 123.90, 123.54, 123.49, 122.46, 120.66, 120.36, 120.06, 119.43, 118.82, 118.33, 109.95, 109.85, 64.86, 46.87, 27.11.

### Synthesis of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (Comp Monomer)

In a nitrogen-filled glovebox, a 100 mL round bottom flask was charged with (4-(3-(4-([1,1′-biphenyl]-4-yl(9,9-dimethyl-9H-fluoren-2-yl)amino)phenyl)-9H-carbazol-9-yl)phenyl)methanol (4.40 g, 6.21 mmol, 1.00 equiv) and 35 mL THF. Sodium hydride (0.224 g, 9.32 mmol, 1.50 equiv) was added in portions, and the mixture stirred for 30 minutes. A reflux condenser was attached, the unit was sealed and removed from the glovebox. 4-vinylbenzyl chloride (1.05 mL, 7.45 mmol, 1.20 equiv) was injected, and the mixture was refluxed until consumption of starting material (TLC). The reaction mixture was cooled (iced bath) and cautiously quenched with isopropanol. Sat. aq. NH₄Cl was added, and the product was extracted with ethyl acetate. Combined organic fractions were washed with brine, dried with MgSO₄, filtered, concentrated, and purified by chromatography on silica (hexanes/ethyl acetate gradient), which delivered the product as a white solid (3.49 g, 67%). ¹H NMR (400 MHz, CDCl₃) δ8.35 (s, 1H), 8.18 (dt, 7=7.8, 1.0 Hz, 1H), 7.74-7.47 (m, 14H), 7.47-7.35 (m, 11H), 7.35-7.23 (m, 9H), 7.14 (s, 1H), 6.73 (dd, J=17.6, 10.9 Hz, 1H), 5.76 (dd, J=17.6, 0.9 Hz, 1H), 5.25 (dd, J=10.9, 0.9 Hz, 1H), 4.65 (s, 4H), 1.45 (s, 6H). ¹³C NMR (101 MHz, CDCl₃) δ 155.13, 153.56, 147.25, 147.03, 146.43, 141.28, 140.61, 140.13, 138.94, 137.64, 137.63, 137.16, 137.00, 136.48, 136.37, 135.06, 134.35, 132.94, 129.21, 128.73, 128.05, 127.96, 127.76, 126.96, 126.94, 126.79, 126.62, 126.48, 126.33, 126.09, 125.14, 124.54, 123.89, 123.54, 123.48, 122.46, 120.66, 120.34, 120.04, 119.44, 118.82, 118.31, 113.92, 110.01, 109.90, 72.33, 71.61, 46.87, 27.11.

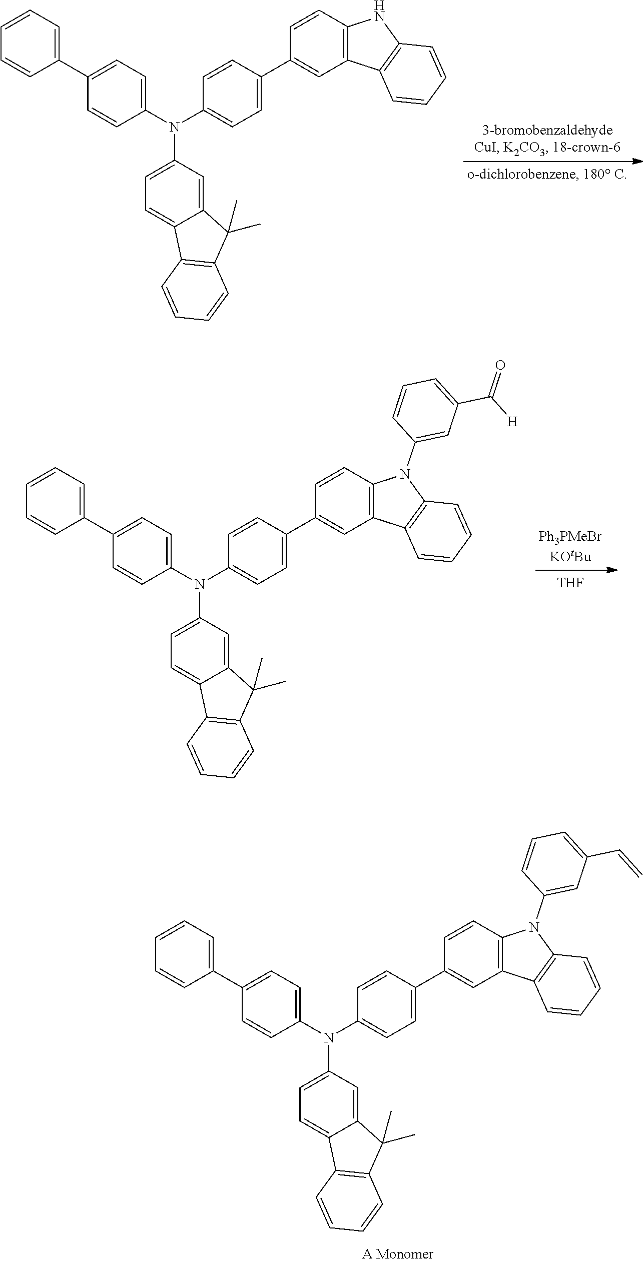 [SMILES: CC1(C)c2ccccc2-c2ccc(N(c3ccc(-c4ccccc4)cc3)c3ccc(-c4ccc5[nH]c6ccccc6c5c4)cc3)cc21 ; CC1(C)c2ccccc2-c2ccc(N(c3ccc(-c4ccccc4)cc3)c3ccc(-c4ccc5c(c4)c4ccccc4n5-c4cccc(C=O)c4)cc3)cc21 ; "THF" ; C=Cc1cccc(-n2c3ccccc3c3cc(-c4ccc(N(c5ccc(-c6ccccc6)cc5)c5ccc6c(c5)C(C)(C)c5ccccc5-6)cc4)ccc32)c1]

### Synthesis of 3-(3-(4-([1,1′-biphenyl]-4-yl(9,9-dimethyl-9H-fluoren-2-yl)amino)phenyl)-9H-carbazol-9-yl)benzaldehyde

A round bottom flask was charged with carbazole (9.10 g, 15.1 mmol, 1.0 equiv), 3-bromobenzaldehyde (2.11 mL, 18.1 mmol, 12 equiv), CuI (0.575 g, 3.02 mmol. 0.2 equiv), potassium carbonate (6.26 g, 45.3 mmol, 3.0 equiv), and 18-crown-6 (399 mg, 10 mol %). The flask was flushed with nitrogen and connected to a reflux condenser. 55 mL of dry, degassed, 1,2-dichlorobenzene was added, and the mixture was heated to 180° C. overnight. Only partial conversion was noted after 14 hours. An additional 2.1 mL of 3-bromobenzaldehyde was added, and heated continued another 24 hours. The solution was cooled and filtered to remove solids. The filtrate was concentrated and adsorbed onto silica for purification by chromatography (0 to 60% dichloromethane in hexanes), which delivered product as a pale yellow solid (8.15 g, 74%). ¹H NMR (500 MHz, CDCl₃) δ 10.13 (s, 1H), 8.39-8.32 (m, 1H), 8.20 (dd, J=7.8, 1.0 Hz, 1H), 8.13 (t, J=1.9 Hz, 1H), 7.99 (d, J=7.5 Hz, 1H), 7.91-7.86 (m, 1H), 7.80 (t, J=7.7 Hz, 1H), 7.70-7.58 (m, 7H), 7.56-7.50 (m, 2H), 7.47-7.37 (m, 6H), 7.36-7.22 (m, 9H), 7.14 (ddd, J=8.2, 2.1, 0.7 Hz, 1H), 1.46 (s, 6H). ¹³C NMR (126 MHz, CDCl₃) δ 191.24, 155.15, 153.57, 147.22, 146.99, 146.60, 140.93, 140.60, 139.75, 138.93, 138.84, 138.17, 136.07, 135.13, 134.42, 133.53, 132.74, 130.75, 128.75, 128.49, 127.97, 127.79, 127.58, 126.97, 126.82, 126.64, 126.51, 126.36, 125.36, 124.47, 124.20, 123.94, 123.77, 123.60, 122.47, 120.68, 120.60, 120.54, 119.45, 118.88, 118.48, 109.71, 109.58, 46.88, 27.12.

### Synthesis of N-([1,1′-biphenyl]-4-yl)-9,9-dimethyl-N-(4-(9-(3-vinylphenyl)-9H-carbazol-3-yl)phenyl)-9H-fluoren-2-amine (A Monomer)

Under a blanket of nitrogen, a round bottom flask was charged with methyltriphenylphosphonium bromide (14.14 g, 39.58 mmol, 2.00 equiv) and 80 mL dry THF. Potassium tert-butoxide (5.55 g, 49.48 mmol, 2.50 equiv) was added in once portion, and the mixture stirred for 15 minutes. Aldehyde (13.99 g, 19.79 mmol, 1.00 equiv) was added in 8 mL dry THF. The slurry stirred at room temperature overnight. The solution was diluted with dichloromethane, and filtered through a plug of silica. The pad was rinsed with several portions of dichloromethane. The filtrate was adsorbed onto silica and purified by chromatography twice (10 to 30% dichloromethane in hexanes), which delivered product as a white solid (9.66 g, 67%) Purity was raised to 99.7% by reverse phase chromatography. ¹H NMR (400 MHz, CDCl₃) δ 8.35 (d, J=1.7 Hz, 1H), 8.18 (dt, J=7.7, 1.0 Hz, 1H), 7.68-7.39 (m, 19H), 7.34-7.23 (m, 9H), 7.14 (dd, J=8.1, 2.1 Hz, 1H), 6.79 (dd, J=17.6, 10.9 Hz, 1H), 5.82 (d, J=17.6 Hz, 1H), 5.34 (d, J=10.8 Hz, 1H), 1.45 (s, 6H). ¹³C NMR (101 MHz, CDCl₃) δ 155.13, 153.57, 147.26, 147.03, 146.44, 141.29, 140.61, 140.13, 139.55, 138.95, 137.99, 136.36, 135.98, 135.06, 134.36, 132.96, 130.03, 128.74, 127.97, 127.77, 126.96, 126.79, 126.63, 126.49, 126.31, 126.11, 125.34, 125.16, 124.67, 124.54, 123.90, 123.55, 123.49, 122.46, 120.67, 120.36, 120.06, 119.44, 118.83, 118.33, 115.27, 110.01, 109.90, 46.87, 27.12. Lab Notebook Reference EXP-15-BD3509.

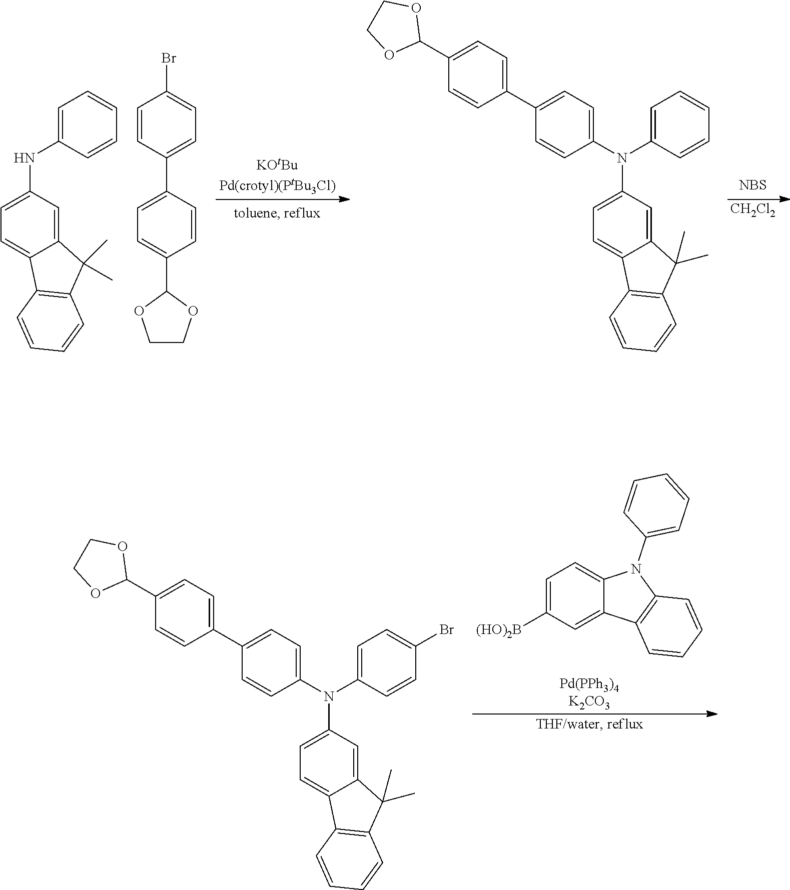

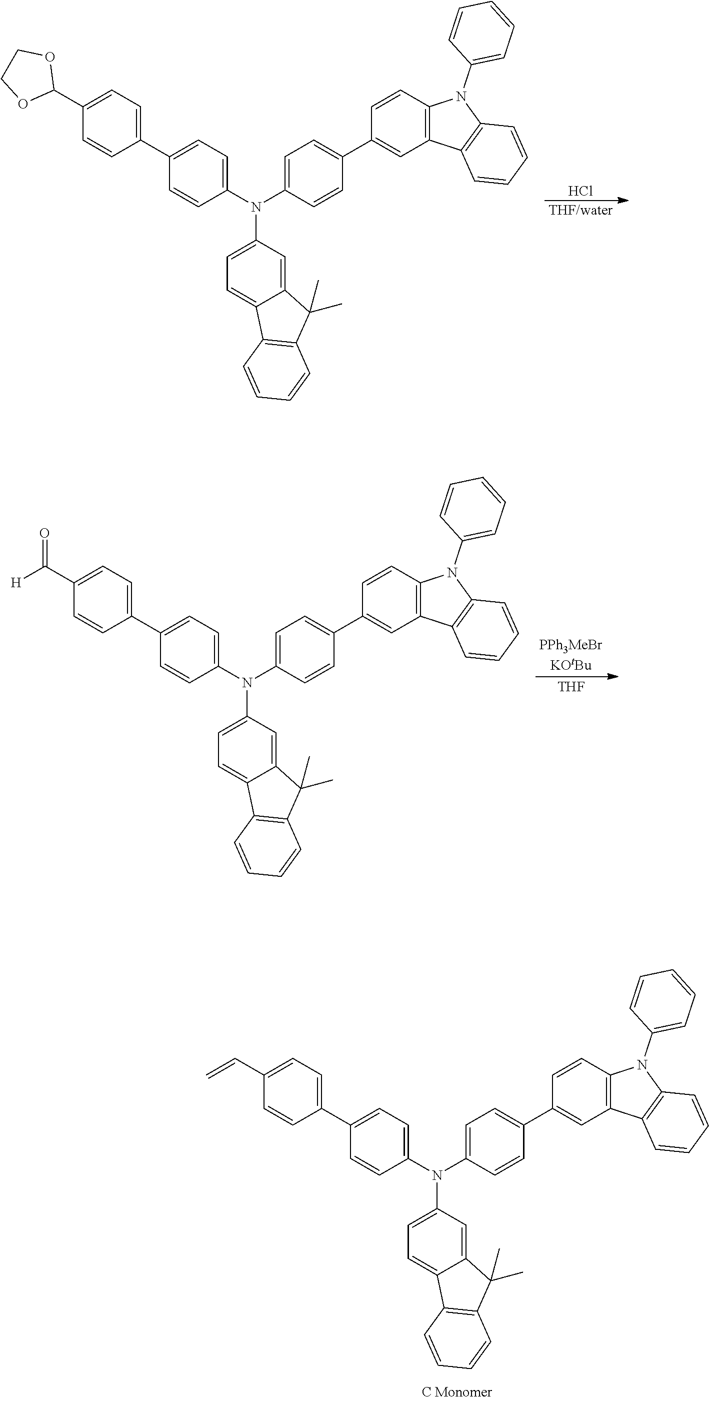

### Synthesis of N-(4′-(1,3-dioxolan-2-yl)-[1,1′-biphenyl]-4-yl)-9,9-dimethyl-N-phenyl-9H-fluoren-2-amine

A 500 mL round bottom flask was charged with 9,9-dimethyl-N-phenyl-9H-fluoren-2-amine (9.91 g, 34.7 mmol, 1.00 equiv), 2-(4′-bromo-[1,1′-biphenyl]-4-yl)-1,3-dioxolane (3.10 g, 7.78 mmol, 1.00 equiv), potassium tert-butoxide (1.31 g, 11.68 mmol, 1.50 equiv), and Pd(crotyl)(P^{t}Bu₃)Cl (0.062 g, 0.16 mmol, 2 mol %). The flask was connected to a reflux condenser and was placed under an atmosphere of nitrogen. 40 mL of dry, nitrogen-sparged toluene was added, and the solution was stirred at 120° C. for overnight. The solution was cooled and filtered through a pad of silica. The silica pad was rinsed with several portions of dichloromethane. The filtrate was adsorbed onto silica and purified by chromatography (10 to 80% dichloromethane in hexanes), which yielded product as a white solid (13.69 g, 73%). ¹H NMR (TOO MHz, CDCl₃) δ 7.64 (d, J=7.3 Hz, 1H), 7.62-7.56 (m, 3H), 7.52 (d, J=8.3 Hz, 2H), 7.48 (d, J=8.8 Hz, 2H), 7.38 (d, J=7.4 Hz, 1H), 7.33-7.21 (m, 5H), 7.20-7.14 (m, 4H), 7.09-7.00 (m, 2H), 5.85 (s, 1H), 4.21-3.97 (m, 4H), 1.42 (s, 6H). ¹³C NMR (126 MHz, CDCl₃) δ 155.07, 153.52, 147.73, 147.46, 147.00, 141.53, 138.89, 136.27, 134.43, 134.36, 129.26, 127.76, 126.94, 126.86, 126.58, 126.48, 124.36, 123.62, 123.57, 122.90, 122.44, 120.62, 119.42, 118.85, 103.63, 65.30, 46.81, 27.06.

### Synthesis of N-(4′-(1,3-dioxolan-2-yl)-[1,1′-biphenyl]-4-yl)-N-(4-bromophenyl)-9,9-dimethyl-9H-fluoren-2-amine

A round bottom flask was charged with N-(4′-(1,3-dioxolan-2-yl)-[1,1′-biphenyl]-yl)-9,9-dimethyl-N-phenyl-9H-fluoren-2-amine (13.7 g, 26.8 mmol, 1.00 equiv). The solid was dissolved in 130 mL of dichloromethane. The mixture was stirred vigorously and N-bromosuccinimide (4.77 g, 26.8 mmol, 1.00 equiv) was added in portions over 30 minutes. The mixture stirred for 24 hours, and was judged complete by TLC. The solution was washed with 1 M NaOH, dried with MgSO₄, and concentrated. The residue was purified by chromatography (30 to 90% dichloromethane in hexanes), which delivered product as a pale yellow solid (15.49 g, 95%). ¹H NMR (400 MHz, CDCl₃) δ 7.64 (ddd, J=7.4, 1.4, 0.7 Hz, 1H), 7.62-7.56 (m, 3H), 7.56-7.51 (m, 2H), 7.51-7.46 (m, 2H), 7.41-7.19 (m, 6H), 7.15 (d, J=6.7 Hz, 2H), 7.07-7.00 (m, 3H), 5.84 (s, 1H), 4.19-3.99 (m, 4H), 1.42 (s, 6H). ¹³C NMR (101 MHz, CDCl₃) δ 155.23, 153.52, 146.93, 146.91, 146.48, 141.36, 138.71, 136.45, 135.04, 134.85, 132.20, 127.91, 126.98, 126.88, 126.66, 126.61, 125.37, 123.92, 123.71, 122.46, 120.75, 119.50, 119.01, 115.01, 103.59, 65.30, 46.85, 27.05.

### Synthesis of N-(4′-(1,3-dioxolan-2-yl)-[1,1′-biphenyl]-4-yl)-9,9-dimethyl-N-(4-(9-phenyl-9H-carbazol-3-yl)phenyl)-9H-fluoren-2-amine

A round bottom flask was charged with the N-(4′-(1,3-dioxolan-2-yl)-[1,1′-biphenyl]-4-yl)-N-(4-bromophenyl)-9,9-dimethyl-9H-fluoren-2-amine (15.1 g, 25.7 mmol, 1.00 equiv), (9-phenyl-9H-carbazol-3-yl)boronic acid (9.58 g, 33.4 mmol, 1.30 equiv), potassium carbonate (10.6 g, 77.0 mmol, 3.00 equiv), and Pd(PPh₃)₄ (0.593 g, 0.513 mmol, 2 mol %). The flask was connected to a reflux condenser and was placed under an atmosphere of nitrogen. 130 mL of nitrogen-sparged 4:1 THF:water was added, and the solution was stirred at 70° C. overnight. The solution was cooled and diluted with water and dichloromethane. Product was extracted with several portions of dichloromethane, and combined organic fractions were dried with MgSO₄. The residue was purified by chromatography (25 to 100% dichloromethane in hexanes), which delivered product as a yellow solid (17.21 g, 82%). ¹H NMR (500 MHz, CDCl₃) δ 8.39-8.31 (m, 1H), 8.18 (dt, J=7.7, 1.1 Hz, 1H), 7.66-7.56 (m, 11H), 7.56-7.48 (m, 4H), 7.48-7.38 (m, 5H), 7.33-7.22 (m, 8H), 7.13 (dd, J=8.2, 2.1 Hz, 1H), 5.85 (s, 1H), 4.20-3.98 (m, 4H), 1.45 (s, 6H). ¹³C NMR (126 MHz, CDCl₃) δ 155.13, 153.56, 147.43, 146.96, 146.36, 141.55, 141.29, 140.14, 138.92, 137.64, 136.45, 136.29, 134.50, 134.40, 132.89, 129.87, 127.97, 127.81, 127.44, 127.01, 126.96, 126.88, 126.60, 126.49, 126.07, 125.12, 124.61, 123.88, 123.74, 123.59, 123.45, 122.46, 120.67, 120.33, 120.01, 119.44, 118.86, 118.31, 109.99, 109.88, 103.64, 65.31, 46.87, 27.11.

### Synthesis of 4′-((9,9-dimethyl-9H-fluoren-2-yl)(4-(9-phenyl-9H-carbazol-3-yl)phenyl)amino)-[1,1′-biphenyl]-4-carbaldehyde

A round bottom flask was charged with N-(4′-(1,3-dioxolan-2-yl)-[1,1′-biphenyl]-4-yl)-9,9-dimethyl-N-(4-(9-phenyl-9H-carbazol-3-yl)phenyl)-9H-fluoren-2-amine (17.21 g, 22.92 mmol, 1.00 equiv). 115 mL tetrahydrofuran was added, followed by aq. HCl (1.00M, 45.8 mL, 2.00 equiv). The flask was connected to a reflux condenser and was stirred for 5 hours at 70° C. The solution was cooled, product was extracted with three portions of dichloromethane Combined organic fractions were washed with water, then sat. aq. NaHCO₃. The solution was dried with MgSO₄, and adsorbed onto silica for purification by chromatography, which yielded the product as a yellow solid (16.0 g, 95%). Higher purity (>99.5%) material could be obtained by reverse phase chromatography. ¹H NMR (400 MHz, CDCl₃) δ 10.02 (s, 1H), 8.36 (dd, J=1.8, 0.6 Hz, 1H), 8.18 (dt, 0.7=7.7, 1.0 Hz, 1H), 7.92 (d, J=8.3 Hz, 2H), 7.75 (d, J=8.3 Hz, 2H), 7.69-7.53 (m, 11H), 7.51-7.38 (m, 5H), 7.36-7.21 (m, 8H), 7.15 (dd, 0.7=8.1, 2.1 Hz, 1H), 1.46 (s, 6H). ¹³C NMR (101 MHz, CDCl₃) δ 191.82, 155.24, 153.58, 148.50, 146.62, 146.57, 146.03, 141.32, 140.21, 138.81, 137.63, 136.97, 134.88, 134.65, 132.77, 132.71, 130.33, 129.89, 128.08, 128.04, 127.49, 127.02, 126.85, 126.67, 126.12, 125.12, 124.99, 123.97, 123.90, 123.43, 123.14, 122.50, 120.77, 120.32, 120.05, 119.53, 119.26, 118.36, 110.03, 109.92, 46.90, 27.11.

### Synthesis of 9,9-dimethyl-N-(4-(9-phenyl-9H-carbazol-3-yl)phenyl)-N-(4′-vinyl-[1,1′-biphenyl]-4-yl)-9H-fluoren-2-amine (C Monomer)

Under a blanket of nitrogen, a round bottom flask was charged with methyltriphenylphosphonium bromide (16.17 g, 45.27 mmol, 2.00 equiv) and 100 mL dry THF. Potassium tert-butoxide (6.35 g, 56.6 mmol, 2.50 equiv) was added in once portion, and the mixture stirred for 15 minutes. 4′-((9,9-dimethyl-9H-fluoren-2-yl)(4-(9-phenyl-9H-carbazol-3-yl)phenyl)amino)-[1,1-biphenyl]-carbaldehyde (16.00 g, 22.63 mmol, 1.00 equiv) was added in 50 mL dry THF. The slurry stirred at room temperature overnight. The solution was quenched with 1 mL of water, and the mixture was filtered through a pad of silica. The pad was rinsed with several portions of dichloromethane. The filtrate was adsorbed to silica, and purified by chromatography (30% dichloromethane in hexane), which delivered product as a white solid (10.18 g, 63%). Reverse phase chromatography brought purity to 99.5%. ¹H NMR (500 MHz, CDCl₃) 58.35 (d, 1=1.7 Hz, 1H), 8.18 (dd, 1=7.8, 1.0 Hz, 1H), 7.67-7.55 (m, 11H), 7.54-7.50 (m, 2H), 7.48-7.37 (m, 1H), 7.33-7.21 (m, 8H), 7.13 (dd, 1=8.1, 2.0 Hz, 1H), 6.74 (dd, 1=17.6, 10.9 Hz, 1H), 5.77 (dd, 1=17.6, 0.9 Hz, 1H), 5.25 (dd, J=10.9, 0.8 Hz, 1H), 1.45 (s, 6H). ¹³C NMR (126 MHz, CDCl₃) δ 155.14, 153.56, 147.31, 146.98, 146.38, 141.30, 140.15, 139.97, 138.93, 137.65, 136.44, 136.08, 134.46, 134.39, 132.90, 129.88, 127.98, 127.56, 127.45, 127.02, 126.97, 126.64, 126.63, 126.50, 126.08, 125.12, 124.59, 123.89, 123.82, 123.57, 123.47, 122.47, 120.68, 120.34, 120.02, 119.45, 118.84, 118.31, 113.56, 110.00, 109.89, 46.87, 27.12.

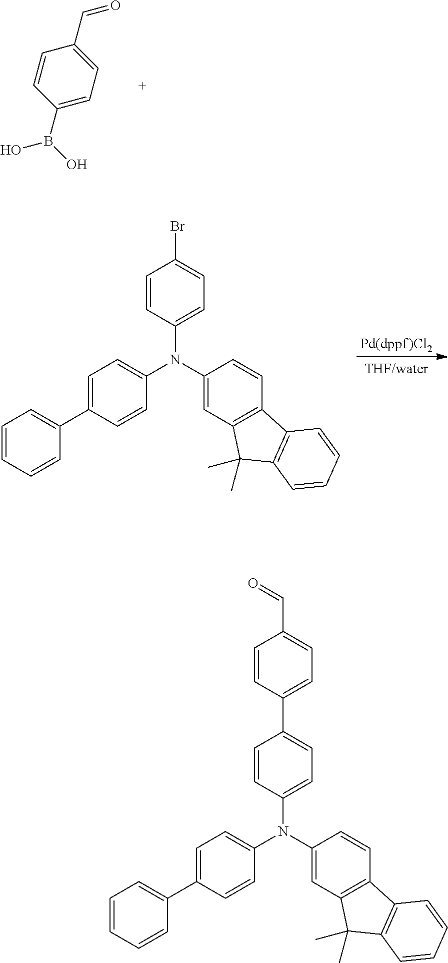 [SMILES: O=Cc1ccc(B(O)O)cc1 ; CC1(C)c2ccccc2-c2ccc(N(c3ccc(Br)cc3)c3ccc(-c4ccccc4)cc3)cc21 ; CC1(C)c2ccccc2-c2ccc(N(c3ccc(-c4ccccc4)cc3)c3ccc(-c4ccc(C=O)cc4)cc3)cc21]

### Synthesis of 4′-([1,1′-biphenyl]-4-yl(9,9-dimethyl-9H-fluoren-2-yl)amino)-[1,1′-biphenyl]-4-carbaldehyde

A 500 mL, 3-neck round bottom flask, fitted with a thermocouple, a condenser with an N₂ inlet, and a septum was charged with N-([1,1′-biphenyl]-4-yl)-N-(4-bromophenyl)-9,9-dimethyl-9H-fluoren-2-amine (18 g, 34.6 mmol, 1 equiv), 4-formylphenylboronic acid (5.75 g, 38.3 mmol, 1 equiv), tetrahydrofuran (285 mL), and 2 M aqueous K₂CO₃ (52 mL). The mixture was stirred and sparged with N₂ for 30 minutes. Pd(dppf)Cl₂ (0.51 g, 0.70 mmol, 0.02 equiv.) was added, and the reaction was heated to reflux for 21 h. Tetrahydrofuran was distilled away, and the reaction was diluted with water (300 mL) and extracted with dichloromethane (2×300 mL). The combined organic phases were dried of MgSO₄, filtered and condensed on to silica. The material was chromatographed using a gradient eluent (1 column volume hexanes increasing to 1:1 hexanes:dichloromethane over 8 column volumes, then maintaining the 1:1 ratio for 10 column volumes). Combined fractions were condensed to yield a bright yellow solid (7.41 g at 99.6% purity, 7.24 g at 98.9% purity, combined yield: 77%). ¹H NMR (400 MHz, C₆D6) δ 9.74 (s, 1H), 7.61 (2H, dd, J=8 Hz, 2 Hz), 7.55 (2H, dd, J=20 Hz, 2.4 Hz), 7.50-7.46 (5H, multiple peaks), 7.37-7.11 (15H, multiple peaks), 1.28 (s, 6H). ¹³C NMR (101 MHz, C₆D6) δ 190.64, 155.70, 153.83, 148.64, 147.24, 147.05, 146.04, 140.76, 139.10, 136.52, 135.61, 135.38, 133.68, 130.22, 129.01, 128.43, 128.36, 127.39, 127.18, 127.12, 126.95, 126.94, 124.93, 124.44, 123.82, 122.74, 121.29, 119.88, 119.61, 46.95, 26.93.

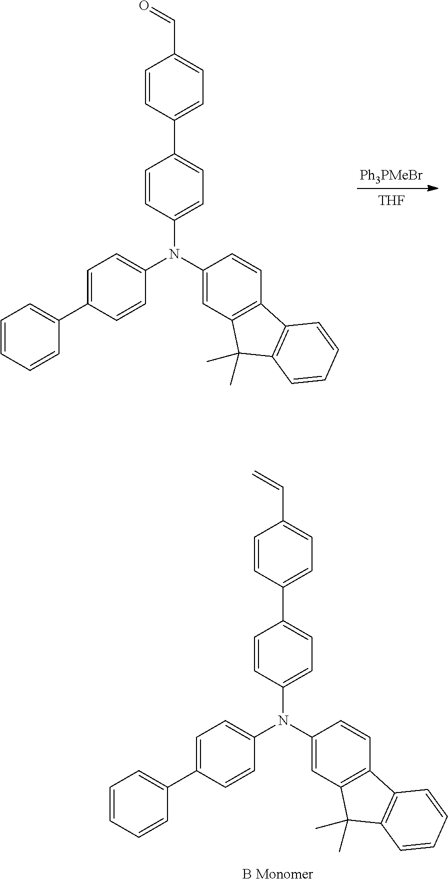 [SMILES: CC1(C)c2ccccc2-c2ccc(N(c3ccc(-c4ccccc4)cc3)c3ccc(-c4ccc(C=O)cc4)cc3)cc21 ; "Ph3PMeBr" ; C=Cc1ccc(-c2ccc(N(c3ccc(-c4ccccc4)cc3)c3ccc4c(c3)C(C)(C)c3ccccc3-4)cc2)cc1 ; "THF"]

### Synthesis of N-([1,1′-biphenyl]-4-yl)-9,9-dimethyl-N-(4′-vinyl-[1,1′-biphenyl]-4-yl)-9H-fluoren-2-amine (B Monomer)

A 250 mL round bottom flask 3-neck round bottom flask, fitted with a thermocouple, a condenser with an N₂ inlet, and a septum was charged with methyltriphenylphosphonium bromide (5.3 g, 5.28 mmol, 2 equiv.) and dry tetrahydrofuran (34 mL). Potassium tert-butoxide (2.08 g, 18.4 mmol, 2.5 equiv.) was added, and the mixture stirred for 15 minutes. 4′-([1,1′-biphenyl]-4-yl(9,9-dimethyl-9H-fluoren-2-yl)amino)-[1,1′-biphenyl]-4-carbaldehyde (3.94 g, 7.3 mmol, 1 equiv.) was dissolved in dry tetrahydrofuran (17 mL) and added to the methyltriphenylphosphonium bromide solution. The reaction was stirred for 16 h at room temperature. Water (0.5 mL) was added, and the mixture was filtered through a pad of silica. The pad was rinsed with dichloromethane, and the filtrate was adsorbed to silica and purified by chromatography using a gradient eluent (1 column volume hexanes increasing to 80:20 hexanes:dichloromethane over 19 column volumes, then maintaining the 80:20 ratio for 10 column volumes). The combined tractions were condensed to yield a white solid (2.62 g at 99.8% purity was isolated, 67% yield). ¹H NMR (400 MHz, C₆D6) δ 7.55-7.43 (multiple peaks, 11H), 7.33-7.10 (multiple peaks 13H), 6.63 (1H, dd, J=20 Hz, 12 Hz) 5.66 (1H, dd, J=20 Hz, 1.2 Hz), 5.11 (1H, dd, J=12 Hz, 1.2 Hz), 1.27 (s, 6H). ¹³C NMR (101 MHz, C₆D6) δ 155.61, 153.85, 147.66, 147.57, 147.39, 140.91, 140.28, 139.25, 136.82, 136.51, 136.04, 135.41, 135.19, 128.98, 128.28, 128.02, 127.78, 127.34, 127.04, 127.02, 126.98, 126.94, 124.60, 124.52, 124.15, 122.71, 121.23, 119.81, 119.30, 113.42, 46.93, 26.94.

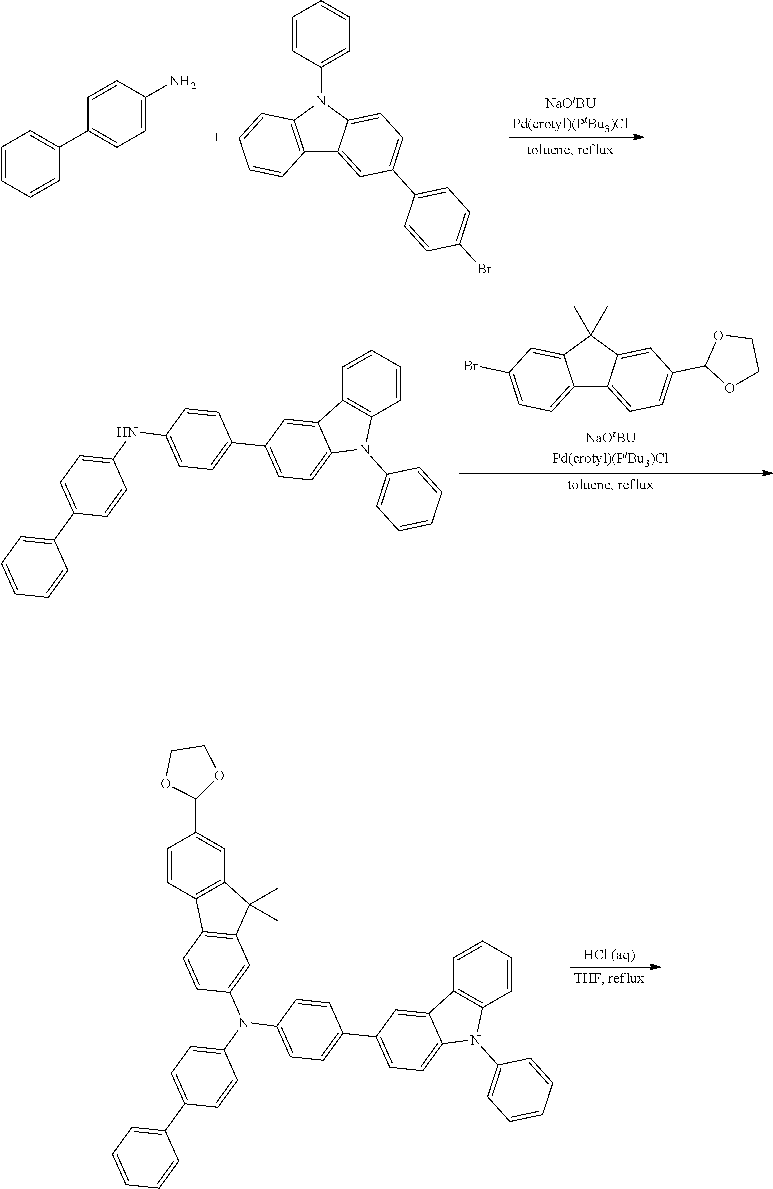 [SMILES: Nc1ccc(-c2ccccc2)cc1 ; Brc1ccc(-c2ccc3c(c2)c2ccccc2n3-c2ccccc2)cc1 ; c1ccc(-c2ccc(Nc3ccc(-c4ccc5c(c4)c4ccccc4n5-c4ccccc4)cc3)cc2)cc1 ; CC1(C)c2cc(Br)ccc2-c2ccc(C3OCCO3)cc21 ; CC1(C)c2cc(C3OCCO3)ccc2-c2ccc(N(c3ccc(-c4ccccc4)cc3)c3ccc(-c4ccc5c(c4)c4ccccc4n5-c4ccccc4)cc3)cc21]

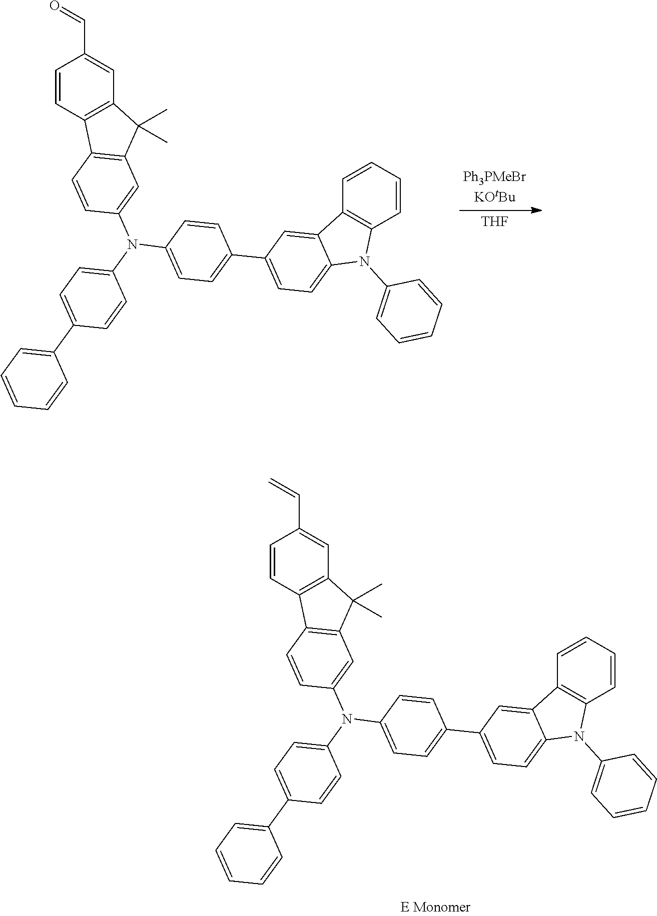 [SMILES: CC1(C)c2cc(C=O)ccc2-c2ccc(N(c3ccc(-c4ccccc4)cc3)c3ccc(-c4ccc5c(c4)c4ccccc4n5-c4ccccc4)cc3)cc21 ; "THF" ; C=Cc1ccc2c(c1)C(C)(C)c1cc(N(c3ccc(-c4ccccc4)cc3)c3ccc(-c4ccc5c(c4)c4ccccc4n5-c4ccccc4)cc3)ccc1-2]

### Synthesis of N-(4-(9-phenyl-9H-carbazol-3-yl)phenyl)-[1,1′-biphenyl]-4-amine

In a N₂-purged glove box, a 500 mL round bottom flask with a Teflon-coated stir bar was charged with 3-(4-bromophenyl)-9-phenyl-9H-carbazole (9.50 g, 23.9 mmol), [1,1′-biphenyl]-4-amine (4.04 g 23.9 mmol), sodium tert-butoxide (3.44 g, 35.8 mmol), chloro(crotyl)(tri-tert-butylphosphine)palladium(II) (0.19 g, 0.48 mmol), and 300 mL of dry, degassed toluene. A reflux condenser was attached and the mixture was heated to 110° C. with stirring for 16 h. The mixture was cooled to room temperature, then diluted with water (150 mL) and ethyl acetate (150 mL). The layers were separated and the aqueous layer was extracted with two additional 150 mL portions of ethyl acetate. The combined organic layers were dried over MgSO₄ and concentrated under reduced pressure. The resulting material was purified by silica gel chromatography eluting with a 0-50% v/v mixture of ethyl acetate and hexane. The material was further purified by reverse phase chromatography eluting with acetonitrile to give the desired product as a white solid (2.82 g 24.3% yield, 99.8% purity), ¹H NMR (400 MHz, Chloroform-d) δ 8.35 (d, J=1.7 Hz, 1H), 8.21 (dt, J=7.7, 1.1 Hz, 1H), 7.69-7.57 (m, 9H), 7.57-7.51 (m, 2H), 7.51-7.39 (m, 6H), 7.35-7.27 (m, 2H), 7.24-7.16 (m, 3H), 5.84 (s, 1H).

### Synthesis of N-([1,1′-biphenyl]-4-yl)-7-(1,3-dioxolan-2-yl)-9,9-dimethyl-N-(4-(9-phenyl-9H-carbazol-3-yl)phenyl)-9H-fluoren-2-amine

In a N₂-purged glove box, a 250 mL round bottom flask with a Teflon-coated stir bar was charged with the 2-(7-bromo-9,9-dimethyl-9H-fluoren-2-yl)-1,3-dioxolane (1.08 g, 3.12 mmol), N-(4-(9-phenyl-9H-carbazol-3-yl)phenyl)-[1,1′-biphenyl]-4-amine (1.52 g, 3.12 mmol), sodium tert-butoxide (0.45 g, 4.69 mmol), chloro(crotyl)(tri-tert-butylphosphine)palladium(II) (0.025 g, 0.06 mmol), and 100 mL of dry, degassed toluene. A reflux condenser was attached and the mixture was heated to 110° C. with stirring for 16 h. The mixture was cooled to room temperature and diluted with water (50 mL) and ethyl acetate (50 mL). The layers were separated and the aqueous layer was extracted with two additional 50 mL portions of ethyl acetate. The combined organic layers were dried over MgSO₄ and concentrated under reduced pressure. A pale orange solid was obtained and used in the next step without purification or characterization, and a yield was not determined

### Synthesis of 7-([1,1′-biphenyl]-4-yl(4-(9-phenyl-9H-carbazol-3-yl)phenyl)amino)-9,9-dimethyl-9H-fluorene-2-carbaldehyde

A 50 mL round bottom flask with a Teflon-coated stir bar was charged with the crude N-([1,1′-biphenyl]-4-yl)-7-(1,3-dioxolan-2-yl)-9,9-dimethyl-N-(4-(9-phenyl-9H-carbazol-3-yl)phenyl)-9H-fluoren-2-amine (2.3 g, 3.06 mmol, theoretical), 30 mL of THF and 7.7 mL of 1.0 M HCl (7.7 mmol). A reflux condenser was attached and the mixture was heated to reflux with stirring overnight. The mixture was cooled to room temperature and 10 mL of water was added. The layers were separated, then the aqueous layer was extracted with three 20 mL portions of dichloromethane. The combined organic layers were washed with 50 mL of a saturated aqueous sodium bicarbonate solution, then dried over MgSO₄ and concentrated under reduced pressure. The residue was purified by flash chromatography on silica gel eluting with 70% v/v mixture of dichloromethane and hexane. The desired product was obtained as a yellow solid (2.02 g, 93.3% yield, 99.6% purity), ¹H NMR (400 MHz, Chloroform-d) δ 10.02 (s, 1H), 8.36 (d, J=1.8 Hz, 1H), 8.18 (dd, J=7.8, 1.1 Hz, 1H), 7.92 (d, J=1.4 Hz, 1H), 7.83 (dd, J=7.8, 1.5 Hz, 1H), 7.75 (d, J=7.8 Hz, 1H), 7.68-7.63 (m, 4H), 7.63-7.58 (m, 6H), 7.58-7.52 (m, 3H), 7.51-7.39 (m, 6H), 7.36-7.25 (m, 7H), 7.16 (dd, J=8.3, 2.1 Hz, 1H), 1.48 (s, 7H). ¹³C NMR (101 MHz, Chloroform-d) δ 192.03, 154.14, 148.84, 146.84, 146.03, 141.35, 140.49, 137.13, 135.87, 134.70, 132.76, 132.02, 130.83, 129.91, 128.79, 128.13, 127.94, 127.51, 127.05, 126.98, 126.69, 126.14, 125.16, 125.13, 124.61, 123.93, 123.45, 122.82, 122.00, 120.33, 120.06, 119.44, 118.39, 117.59, 110.05, 109.94, 46.94, 26.88.

### Synthesis of N-([1,1′-biphenyl]-4-yl)-9,9-dimethyl-N-(4-(9-phenyl-9H-carbazol-3-yl)phenyl)-7-vinyl-9H-fluoren-2-amine (E Monomer)

In a N₂-purged glove box an oven dried 100 mL jar with a Teflon-coated stir bar was charged with methyltriphenylphosphonium bromide (2.04 g, 5.72 mmol), and 50 mL of dry, degassed THF. Potassium tertbutoxide (0.80 g, 7.14 mmol) was added and the mixture was stirred for 15 min. A solution of 7-([1,1′-biphenyl]-4-yl(4-(9-phenyl-9H-carbazol-3-yl)phenyl)amino)-9,9-dimethyl-9H-fluorene-2-carbaldehyde (2.02 g, 2.86 mmol) in 10 mL of THF was added and the resulting slurry was stirred at room temperature for 16 h. The mixture was quenched by addition of water and extracted with three 50 mL portions of dichloromethane. The organic layers were combined, dried over MgSO₄ and concentrated under reduced pressure. The residue was purified by flash chromatography on silica gel eluting with a 55% v/v mixture of dichloromethane and hexane. The desired product was obtained as a yellow solid (1.56 g, 77.4% yield, 99.5% purity). ¹H NMR (400 MHz, Chloroform-d) δ 8.35 (d, J=1.7 Hz, 1H), 8.18 (dd, J=7.8, 10 Hz, 1H), 7.68-7.56 (m, 11H), 7.55-7.50 (m, 2H), 7.48-7.40 (m, 7H), 7.37 (dd, J=7.9, 1.6 Hz, 1H), 7.34-7.25 (m, 7H), 7.13 (dd, J=8.2, 2.1 Hz, 1H), 6.79 (dd, J=17.6, 10.9 Hz, 1H), 5.79 (dd, J=17.6, 1.0 Hz, 1H), 5.27-5.20 (m, 1H), 1.46 (s, 6H). ¹³C NMR (101 MHz, Chloroform-7) δ 155.47, 153.93, 147.22, 147.11, 146.40, 141.33, 140.62, 140.17, 138.89, 137.68, 137.25, 136.48, 135.99, 135.15, 129.88, 128.75, 127.99, 127.79, 127.45, 127.03, 126.81, 126.64, 126.09, 125.64, 125.14, 124.62, 123.98, 123.91, 123.49, 120.70, 120.34, 120.08, 120.03, 119.47, 118.69, 118.33, 112.81, 110.01, 109.90, 46.81, 27.14.

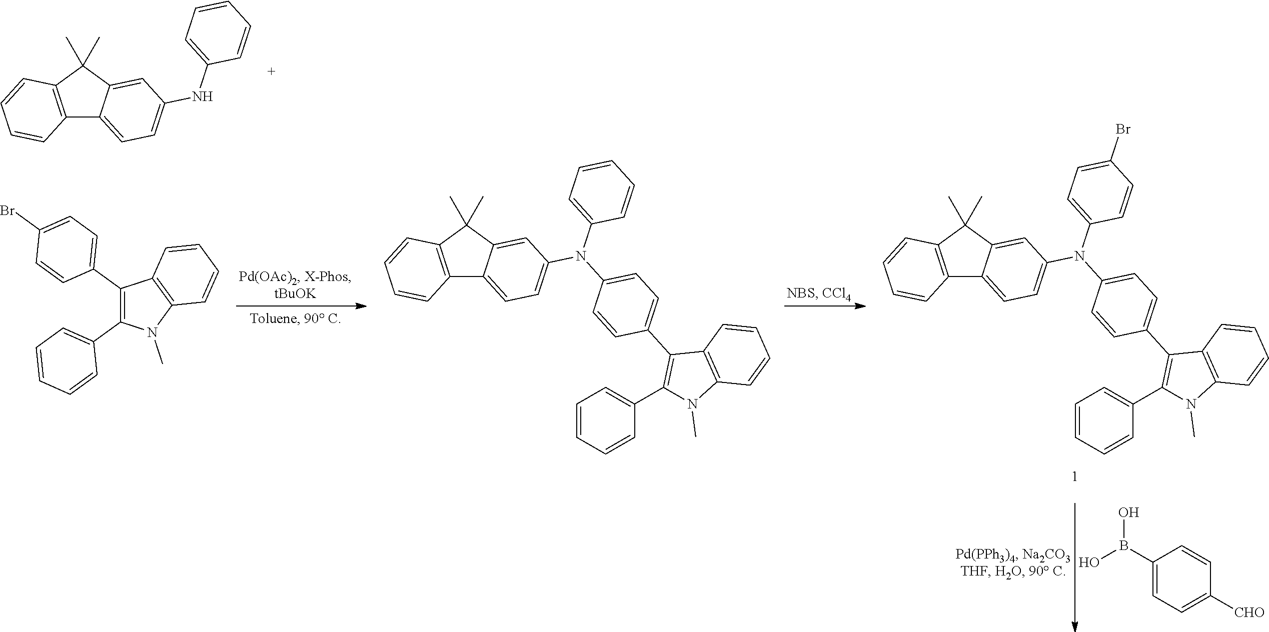 [SMILES: CC1(C)c2ccccc2-c2ccc(Nc3ccccc3)cc21 ; Cn1c(-c2ccccc2)c(-c2ccc(Br)cc2)c2ccccc21 ; Cn1c(-c2ccccc2)c(-c2ccc(N(c3ccccc3)c3ccc4c(c3)C(C)(C)c3ccccc3-4)cc2)c2ccccc21 ; Cn1c(-c2ccccc2)c(-c2ccc(N(c3ccc(Br)cc3)c3ccc4c(c3)C(C)(C)c3ccccc3-4)cc2)c2ccccc21 ; O=Cc1ccc(B(O)O)cc1]

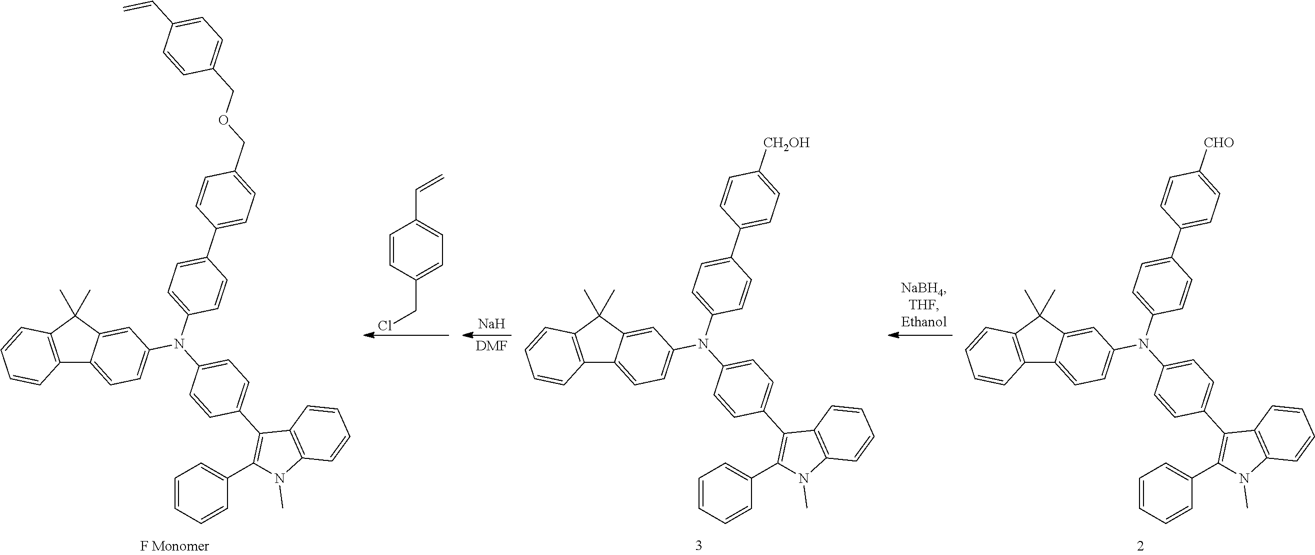

### Synthesis of 4′-((9,9-dimethyl-9H-fluoren-2-yl)(4-(l-methyl-2-phenyl-1H-indol-3-yl)phenyl) amino)-[1,1′-biphenyl]-4-carbaldehyde (2)

A mixture of N-(4-bromophenyl)-9,9-dimethyl-N-(4-(1-methyl-2-phenyl-1H-indol-3-yl)phenyl)-9H-fluoren-2-amine (1) (12.9 g 20 mmol), (4-formylphenyl) boronic acid (1.07 g, 30 mmol), Pd(PPh₃)₄ (693 mg 1155, 3%), 2M K₂CO₃ (4.14 g 30 mmol, 15 mL H2O), and 45 mL of THF was heated at 80° C. under nitrogen atmosphere for 12 h. After cooling to room temperature, the solvent was removed under vacuum and the residue was extracted with dichloromethane. After cooling to room temperature, the solvent was removed under vacuum and then water was added. The mixture was extracted with CH₂Cl₂. The organic layer was collected and dried over anhydrous sodium sulphate. After filtration, the filtrate was evaporated to remove solvent and the residue was purified through column chromatography on silica gel to give light-yellow solid (yield: 75%). MS (ESI): 671.80 [M+H]₊. 1H-NMR (CDCl₃, 400 MHz, TMS, ppm): δ 10.03 (s, 1H), 7.94 (d, 2H), 7.75 (d, 2H), 7.64 (m, 2H), 7.55 (d, 2H), 7.41 (m, 9H), 7.23 (m, 8H), 7.09 (m, 3H), 3.69 (s, 3H), 1.43 (s, 6H).

### Synthesis of (4′-((9,9-dimethyl-9H-fluoren-2-yl)(4-(l-methyl-2-phenyl-1H-indol-3-yl) phenyl)amino)-[1,1′-biphenyl]-4-yl)methanol (3)

To a solution of (2) (10 g, 15 mmol) in 50 mL THF and 50 mL ethanol at 40° C., NaBH₄ (2.26 g, 60 mmol) was added under nitrogen atmosphere. The solution was allowed to stir at room temperature for 2 h. Then, aqueous hydrochloric add solution was added until pH 5 and the addition was maintained for a further 30 min. The solvent was removed under vacuum and the residue was extracted with dichloromethane. The product was then obtained by remove of solvent and used for next step without further purification (yield: 95%). MS (ESI): 673.31 [M+H]⁺.

### Synthesis of 9,9-dimethyl-N-(4-(1-methyl-2-phenyl-1H-indol-3-yl)phenyl)-N-(4′-(((4-vinylbenzyl)oxy)methyl)-[1,1′-biphenyl]-4-yl)-9H-fluoren-2-amine (F Monomer)

To a solution of (3) (9.0 g, 13.4 mmol) in 50 mL dry DMF was added NaH (482 mg, 20.1 mmol), the mixture was then stirred at room temperature for 1 h. And 4-vinylbenzyl chloride (3.05 g, 20.1 mmol) was added to above solution via syringe. The mixture was heated to 50° C. for 24 h. After quenched with water, the mixture was poured into water to remove DMF. The residue was filtrated and the resulting solid was dissolved with dichloromethane, which was then washed with water. The solvent was removed under vacuum and the residue was extracted with dichloromethane. The product was then obtained by column chromatography on silica gel (yield: 90%). MS (ESI): 789.38 [M+H]⁺. 1H-NMR (CDCl₃, 400 MHz, TMS, ppm): δ 7.59 (d, 4H), 7.48 (m, 2H), 7.40 (m, 18H), 7.22 (m, 8H), 6.71 (dd, 1H), 5.77 (d, 1H), 5.25 (d, 1H), 4.58 (s, 4H), 3.67 (s, 3H), 1.42 (s, 6H).

### General Protocol for Radical Polymerization of Charge Transporting Monomers

In a glovebox, charge transporting monomer (1.00 equiv) was dissolved in anisole (electronic grade, 0.25 M). The mixture was heated to 70° C., and AIBN solution (0.20 M in toluene, 5 mol %) was injected. The mixture was stirred until complete consumption of monomer, at least 24 hours (2.5 mol % portions of AIBN solution can be added to complete conversion). The polymer was precipitated with methanol (10× volume of anisole) and isolated by filtration. The filtered solid was rinsed with additional portions of methanol. The filtered solid was re-dissolved in anisole and the precipitation/filtration sequence repeated twice more. The isolated solid was placed in a vacuum oven overnight at 50° C. to remove residual solvent.

### Molecular Weight Data for Charge Transporting Polymers:

Gel permeation chromatography (GPC) studies were carried out as follows. 2 mg of charge transporting polymer was dissolved in 1 mL THF. The solution was filtrated through a 0.20 μm polytetrafluoroethylene (PTFE) syringe filter and 50 μl of the filtrate was injected onto the GPC system. The following analysis conditions were used: Pump: Waters™ e2695 Separations Modules at a nominal flow rate of 1.0 mL/min; Eluent: Fisher Scientific HPLC grade THF (stabilized); Injector: Waters e2695 Separations Modules; Columns: two 5 μm mixed-C columns from Polymer Laboratories Inc., held at 40° C.; Detector: Shodex RI-201 Differential Refractive Index (DRI) Detector; Calibration: 17 polystyrene standard materials from Polymer Laboratories Inc., fit to a 3rd order polynomial curve over the range of 3,742 kg/mol to 0.58 kg/mol.

| Monomer | Mₙ | M_{w} | M_{z} | M_{z+l} | M_{w}/Mₙ |
|---|---|---|---|---|---|
| Comp | 17,845 | 38,566 | 65,567 | 95,082 | 2.161 |
| A | 23,413 | 88,953 | 176,978 | 266,718 | 3.799 |
| C | 22,348 | 93,724 | 196,464 | 302,526 | 4.194 |
| B | 22,175 | 58,355 | 101,033 | 148,283 | 2.632 |
| D | 15,704 | 61,072 | 124,671 | 227,977 | 3.889 |
| E | 25,139 | 59,034 | 108,767 | 163,606 | 2.348 |
| F, low MW | 4,606 | 8,233 | 13,254 | 22,789 | 1.79 |
| F, high Mw | 27,171 | 59,262 | 104,762 | 157,817 | 2.18 |

### HTL Homopolymer Film Study—Solvent Orthogonality:

1) Preparation of HTL homopolymer solution: charge transporting homopolymer solid powders were directly dissolved into anisole to make a 2 wt % stock solution. The solution was stirred at 80° C. for 5 to 10 min in N₂ for complete dissolving.
2) Preparation of thermally annealed HTL homopolymer film: Si wafer was preheated by UV-ozone for 2 min prior to use. Several drops of the above filtered HTL solution were deposited onto the pre-treated Si wafer. The thin film was obtained by spin coating at 500 rpm for 5 s and then 2000 rpm for 30 s. The resulting film was then transferred into the N₂ purging box. The “wet” film was prebaked at 100° C. for Iminio remove most of residual anisole. Subsequently, the film was thermally annealed at 160 to 235° C. for 10 to 20 min
3) Strip test on thermally annealed HIL homopolymer film: The “Initial” thickness of thermally annealed HTL film was measured using an M-2000D ellipsometer (J. A Woolam Co., Inc.). Then, several drops of o-xylene or anisole were added onto the film to form a puddle. After 90 s, the o-xylene/anisole solvent was spun off at 3500 rpm for 30 s. The “Strip” thickness of the film was immediately measured using the ellipsometer. The film was then transferred into die N₂ purging box, followed by post-baking at 100° C. for 1 min to remove any swollen solvent in the film. The “Final” thickness was measured using the ellipsometer. The film thickness was determined using Cauchy model and averaged over 9=3×3 points in a 1 cm×1 cm area.

“−Strip”=“Strip”−“Initial”: Initial film loss due to solvent strip

“−PSB”=“Final”−“Strip”: Further film loss of swelling solvent

“−Total”=“−Strip”+“−PSB”=“Final”−“Initial”: Total film loss due to solvent strip and swelling

Strip tests were applied for studying HTL homopolymer orthogonal solvency. For a fully solvent resistant HTL film, the total film loss after solvent stripping should be <1 nm, preferably <0.5 nm.

High MW comp, low MW F homopolymer films are not orthogonal to o-xylene. High MW F homopolymer films are orthogonal to o-xylene only at low thermal annealing temperature (e.g. 180°Q High MW A and C, medium MW B, and E homopolymer films are orthogonal to o-xylene. High MW C homopolymer film is orthogonal to anisole at annealing temperature close to its T_{g}. None of the other tested HTL homopolymer films are orthogonal to anisole.

Summary Table: High MW A homopolymer strip test results (o-xylene as stripping solvent)

| | | | | | | |
|---|---|---|---|---|---|---|
| Annealing | Initial (nm) | Strip (nm) | −Strip (nm) | Final (nm) | −PSB (nm) | −Total (nm) |

1.5 min o-xylene stripping test

| | | | | | | |
|---|---|---|---|---|---|---|
| 160 C./20 min | 35.58 ± 0.13 | 22.66 ± 1.49 | −12.92 | 22.67 ± 1.49 | 0.01 | −12.91 |
| 180 C./20 min | 42.34 ± 0.05 | 42.95 ± 0.08 | 0.61 | 42.71 ± 0.24 | −0.24 | 0.37 |
| 205 C./10 min | 43.64 ± 0.06 | 43.96 ± 0.06 | 0.32 | 43.58 ± 0.04 | −0.39 | −0.06 |

5 min o-xylene stripping test

| | | | | | | |
|---|---|---|---|---|---|---|
| 180 C./20 min | 43.47 ± 0.09 | 43.63 ± 0.26 | −0.16 | 43.03 ± 0.20 | −0.59 | −0.43 |
| 205 C./10 min | 42.65 ± 0.06 | 43.22 ± 0.08 | 0.57 | 42.63 ± 0.05 | −0.59 | −0.02 |

Summary Table: Medium MW B homopolymer strip test results (o-xylene as stripping solvent)

| | | | | | | |
|---|---|---|---|---|---|---|
| Annealing | Initial (nm) | Strip (nm) | −Strip (nm) | Final (nm) | −PSB (nm) | −Total (nm) |

1.5 min o-xylene stripping test

| | | | | | | |
|---|---|---|---|---|---|---|
| 160 C./20 min | 40.76 ± 0.06 | 41.23 ± 0.15 | +0.46 | 40.76 ± 0007 | −0.46 | −0.00 |
| 180 C./20 min | 40.39 ± 0.12 | 40.84 ± 0.11 | +0.45 | 40.41 ± 0.14 | −0.43 | +0.02 |
| 190 C./20 min | 40.35 ± 0.16 | 40.72 ± 0.24 | +0.37 | 40.28 ± 0.18 | −0.44 | −0.07 |
| 205 C./10 min | 42.03 ± 0.15 | 42.40 ± 0.09 | +0.37 | 42.00 ± 0.11 | −0.40 | −0.03 |

5 min o-xylene stripping test

| | | | | | | |
|---|---|---|---|---|---|---|
| 160 C./20 min | 41.70 ± 0.07 | 0.94 ± 0.30 | −40.76 | N/A | N/A | N/A |
| 180 C./20 min | 41.32 ± 0.13 | 40.24 ± 0.13 | −1.08 | 39.95 ± 0.13 | −0.29 | −1.36 |
| 190 C./20 min | 41.30 ± 0.28 | 35.15 ± 0.70 | −6.15 | 34.97 ± 0.65 | −0.18 | −6.33 |
| 205 C./10 min | 42.92 ± 0.10 | 22.33 ± 2.92 | −20.59 | 21.13 ± 2.66 | −1.20 | −21.79 |

Summary Table: High MW homopolymer F strip test results (o-xylene as stripping solvent)

| | Strip | | | | | | |
|---|---|---|---|---|---|---|---|
| | Solvent | | | | | | |
| Annealing | (1.5 min. | Initial (nm) | Strip (nm) | −Strip (nm) | Final (nm) | −PSB (nm) | −Total (nm) |
| 180 C. 20 min | o-xylene | 39.79 ± 0.12 | 39.38 ± 0.22 | −0.41 | 38.89 ± 0.17 | −0.49 | −0.90 |
| 205 C. 10 min | o-xylene | 40.71 ± 0.10 | 21.15 ± 4.50 | −19.56 | 21.42 ± 4.46 | +0.28 | −19.28 |

Summary Table: High MW C homopolymer strip test results (o-xylene and anisole as stripping solvents)

| Annealing | Strip Solvent | Initial (nm) | Strip (nm) | −Strip (nm) | Final (nm) | −PSB (nm) | −Total (nm) |
|---|---|---|---|---|---|---|---|
| 160 C. 20 min | 1.5 min o-xylene | 43.72 ± 0.23 | 43.98 ± 0.21 | +0.26 | 43.73 ± 0.07 | −0.25 | +0.01 |
| 180 C. 20 min | 1.5 min o-xylene | 43.55 ± 0.12 | 43.61 ± 0.13 | +0.07 | 43.43 ± 0.11 | −0.18 | −0.12 |
| 180 C. 20 min | 5 min o-xylene | 43.43 ± 0.18 | 43.83 ± 0.14 | +0.40 | 43.43 ± 0.14 | −0.40 | −0.00 |
| 180 C. 20 min | 1.5 min Anisole | 43.43 ± 0.11 | 37.46 ± 1.07 | −5.97 | 37.26 ± 1.16 | −0.20 | −6.17 |
| 205 C. 10 min | 1.5 min o-xylene | 42.92 ± 0.08 | 42.95 ± 0.03 | +0.02 | 42.77 ± 0.04 | −0.18 | −0.15 |
| 205 C. 10 min | 5 min o-xylene | 43.09 ± 0.07 | 43.22 ± 0.09 | +0.13 | 43.01 ± 0.09 | −0.21 | −0.08 |
| 205 C. 10 min | 1.5 min Anisole | 42.77 ± 0.04 | 41.19 ± 0.21 | −1.58 | 40.84 ± 0.17 | −0.35 | −1.93 |
| 220 C. 10 min | 1.5 min o-xylene | 44.08 ± 0.11 | 44.11 ± 0.10 | +0.03 | 43.92 ± 0.11 | −0.19 | −0.16 |
| 220 C. 10 min | 1.5 min Anisole | 43.92 ± 0.11 | 37.53 ± 0.50 | −6.39 | 37.26 ± 0.36 | −0.28 | −6.66 |
| 235 C. 10 min | 1.5 min o-xylene | 43.36 ± 0.08 | 43.65 ± 0.07 | +0.29 | 43.26 ± 0.08 | −0.39 | −0.11 |
| 235 C. 10 min | 1.5 min Anisole | 43.26 ± 0.08 | 35.60 ± 2.28 | −7.65 | 35.08 ± 2.09 | −0.53 | −8.18 |

Summary Table: High MW E homopolymer strip test results (o-xylene as stripping solvent)

| Annealing | Strip Solvent | Initial (nm) | Strip (nm) | −Strip (nm) | Final (nm) | −PSB (nm) | −Total (nm) |
|---|---|---|---|---|---|---|---|
| 160 C. 20 min | 1.5 min o-xylene | 40.59 ± 0.10 | 32.09 ± 0.22 | −8.50 | 31.79 ± 0.21 | −0.29 | −8.79 |
| 180 C. 20 min | 1.5 min o-xylene | 39.52 ± 0.09 | 39.68 ± 0.13 | +0.15 | 39.21 ± 0.06 | −0.46 | −0.31 |
| 180 C. 20 min | 5 min o-xylene | 39.21 ± 0.06 | 21.77 ± 0.35 | −17.45 | 21.51 ± 0.41 | −0.26 | −17.70 |
| 205 C. 10 min | 1.5 min o-xylene | 38.83 ± 0.13 | 39.14 ± 0.07 | +0.31 | 38.70 ± 0.10 | −0.44 | −0.14 |
| 205 C. 10 min | 5 min o-xylene | 38.70 ± 0.10 | 39.18 ± 0.09 | +0.49 | 38.56 ± 0.10 | −0.62 | −0.14 |
| 220 C. 10 min | 1.5 min o-xylene | 41.52 ± 0.52 | 42.05 ± 0.19 | +0.53 | 41.68 ± 0.24 | −0.37 | +0.16 |
| 220 C. 10 min | 5 min O-xylene | 41.68 ± 0.24 | 42.15 ± 0.17 | +0.47 | 41.39 ± 0.21 | −0.76 | −0.29 |
| 235 C. 10 min | 1.5 min o-xylene | 42.32 ± 0.09 | 42.51 ± 0.05 | +0.19 | 42.15 ± 0.08 | −0.36 | −0.16 |
| 235 C. 10 min | 5 min o-xylene | 42.15 ± 0.08 | 42.40 ± 0.10 | +0.25 | 41.78 ± 0.12 | −0.62 | −0.38 |

### Preparation of Light Emitting Device

Indium tin oxide (TTO) glass substrates (2*2 cm) were cleaned with solvents ethanol, acetone, and isopropanol by sequence, and then were treated with a UV Ozone cleaner for 15 min. The hole injection layer (HIL) material Plexcore™ OC AQ-1200 from Plextronics Company was spin-coated from water solution onto the ITO substrates in glovebox and annealed at 150° C. for 20 min. After that, for comparative evaporative HIL, N-([1,1′-biphenyl]-4-yl)-9,9-dimethyl-N-(4-(9-phenyl-9H-carbazol-3-yl)phenyl)-9H-fluoren-2-amine, the substrate was transferred into a thermal evaporator for the deposition of the HTL, emitting materials layer (EML), electron transfer layer (ETL) and cathode; for inventive HTL for solution process, HTL materials (soluble copolymers) were deposited from anisole solution and annealed at 150° C. for 10 min to remove organic solvent. After that, the crosslinking of polymeric HTL was carried out on a hotplate in glovebox at 205° C. for 10 min. Then subsequent phosphorescent green (Ph-Green) EML, ETL and cathode were deposited in sequence. Finally these devices were hermetically sealed prior to testing.

The current-voltage-luminance (J-V-L) characterizations for the OLED devices, that is, driving voltage (V), luminance efficiency (Cd/A), and international commission on illumination (CIE) data at 1000 nit and 50 mA/cm² luminance, and lifetime at 15000 nit for 10 hr were performed with a Keithly™ 238 High Current Source-Measurement Unit and a CS-100A Color and Luminance Meter from Konica Minolta Company and were listed in Table 2. Electroluminescence (EL) spectra of the OLED devices were collected by a calibrated CCD spectrograph and were fixed at 516 nm for all the four OLED device examples.

| HTL Material | Voltage at 10 mA/cm² | Voltage at 100 mA/cm² |
|---|---|---|
| Comp | 1.6 V | 2.9 V |
| A | 2.5 V | 4.2 V |
| B | 3.0 V | 4.5 V |

| | | | | | | Lifetime | |
|---|---|---|---|---|---|---|---|
| | | | Voltage [V, | Efficiency | | [%, 10 hr] | EL |
| Device structure | | | 1000 nit] | [cd/A] | CIE | 15000 nit | (nm) |
| T068(800)/L101(50)/T070(400) | | HP405:Ir1A18 | 2.9 | 74.3 | 310 | 97.7 | 520 |
| | | (15%) | | | 638 | | |
| Plexcore | Evap T070(400) | | 3.2 | 69.9 | 316 | 98.5 | 516 |
| AQ1200 | | | | | 629 | | |
| | Comp | | 3.3 | 70.8 | 312 | 96.7 | 516 |
| | Homopolymer | | | | 631 | | |
| | A Homopolymer | | 3.5 | 66.4 | 313 | 95.8 | 516 |
| | | | | | 630 | | |
| | B Homopolymer | | 4.3 | 68.4 | 312 | 96.8 | 516 |
| | | | | | 632 | | |

1. A polymer having Mₙ at least 4,000 and comprising polymerized units of a compound of formula NAr¹Ar²Ar³, wherein Ar¹, Ar² and Ar³ independently are C₆-C₄₀ aromatic substituents; Ar¹, Ar² and Ar³ collectively contain no more than one nitrogen atom and at least one of Ar¹, Ar² and Ar³ contains a vinyl group attached to an aromatic ring.

2. The polymer of claim 1 having Mₙ from 6,000 to 1,000,000.

3. The polymer of claim 2 in which the compound of formula NAr¹Ar²Ar³ contains a total of 4 to 12 aromatic rings.

4. The polymer of claim 3 in which each of Ar¹, Ar² and Ar³ independently contains from 10 to 32 carbon atoms.

5. The polymer of claim 4 in which Ar groups contain no heteroatoms other than nitrogen.

6. The polymer of claim 5 in which only one vinyl group is present in the compound of formula NAr¹Ar²Ar³.

7. The polymer of claim 6 in which Ar groups consist of one or more of biphenylyl, fluorenyl, phenylenyl, carbazolyl and indolyl.

8. An electronic device comprising one or more polymers of claim 1.

9. A light emitting device comprising one or more polymers of claim 1.
